(19) United States
(12) Patent Application Publication
(10) Pub. No.: US 2018/0138337 A1
(43) Pub. Date: May 17, 2018

(54) Transparent Conductive Adhesive Materials

(71) Applicant: Alliance for Sustainable Energy, LLC, Golden, CO (US)

(72) Inventors: Adele Clare Tamboli, Golden, CO (US); Benjamin Guocian Lee, Leipzig (DE); Pauls Stradins, Golden, CO (US); Marinus Franciscus Antonius Maria van Hest, Lakewood, CO (US); Talysa Renae Klein, Bailey, CO (US)

(21) Appl. No.: 15/812,610

(22) Filed: Nov. 14, 2017

Related U.S. Application Data
(60) Provisional application No. 62/422,475, filed on Nov. 15, 2016.
(60) Provisional application No. 62/445,587, filed on Jan. 12, 2017.

(51) Int. Cl. H01L 31/043; H01L 31/05; H01L 31/068; H01L 31/0236; H01L 31/0224; B32B 7/12; B32B 15/04

(52) U.S. Cl. CPC H01L 31/043; H01L 31/0516; H01L 31/0682; H01L 31/0512; H01L 31/02363; B32B 2457/12; B32B 7/12; B32B 15/04; B32B 2307/412; B32B 2307/202; B32B 2309/105; H01L 31/022441

(57) ABSTRACT

Transparent and conductive adhesive (TCA) materials that may be incorporated into various devices are provided. According to an aspect of the invention, a device includes a first layer, a second layer, and a third layer including a TCA material. The third layer is arranged between the first layer and the second layer, and is configured to provide electrical conductivity between the first layer and the second layer. The TCA material includes conductive elements dispersed within a transparent adhesive, and the conductive elements are deformable.

### CROSS-REFERENCE TO RELATED APPLICATIONS

This application claims priority under 35 U.S.C. § 119 to U.S. Provisional Patent Application No. 62/422,475, filed on Nov. 15, 2016, and to U.S. Provisional Patent Application No. 62/445,587, filed on Jan. 12, 2017, the contents of which are hereby incorporated by reference in their entireties.

### CONTRACTUAL ORIGIN

The United States Government has rights in this invention under Contract No. DE-AC36-08G028308 between the United States Department of Energy and Alliance for Sustainable Energy, LLC, the Manager and Operator of the National Renewable Energy Laboratory.

### BACKGROUND OF THE INVENTION

The present invention relates to transparent conductive adhesive materials that may be used in a variety of applications. There is a need in various fields, such as photovoltaic (PV) devices, light-emitting diodes (LEDs), and other optoelectronic devices, for materials that can bond various electronic layers and provide electrical conductivity between the electronic layers, while being transparent to an appropriate portion of the electromagnetic spectrum. However, some related art materials, such as In₂O₃—SnO₂ (ITO) particle composites, are incompatible with textured surfaces and require costly high-temperature annealing. Further, carbon nanotube composites, flat metal nanowire laminates, and metal nanofiber composites provide primarily in-plane conductivity with limited out-of-plane conductivity. In addition, materials based on poly(3,4-ethylenedioxythiophene) (PEDOT) have poor optical properties when grown thick enough to accommodate unpolished silicon surfaces.

### SUMMARY OF THE INVENTION

Exemplary embodiments of the invention provide transparent and conductive adhesive (TCA) materials that may be incorporated into various devices. According to an aspect of the invention, a device includes a first layer, a second layer, and a third layer including a TCA material. The third layer is arranged between the first layer and the second layer, and is configured to provide electrical conductivity between the first layer and the second layer. The TCA material includes conductive elements dispersed within a transparent adhesive, and the conductive elements are deformable.

The conductive elements may include plastic spheres that are coated with metal. The plastic spheres may include poly(methyl methacrylate) (PMMA). An area percent coverage of the conductive elements within the transparent adhesive may be below 22. A diameter of each of the conductive elements within the transparent adhesive may be between 200 nm and 1000 μm. For example, the diameter may be between 45 μm and 53 μm.

The conductive elements may include metal spheres with dendrites that connect the metal spheres to the first layer or the second layer. The transparent adhesive may include ethylene-vinyl acetate (EVA).

A series resistance of the third layer along a direction perpendicular to a plane of the third layer may be less than 1 Ω·cm². The third layer may be configured to provide no electrical conductivity along a direction parallel to the plane of the third layer.

The first layer and/or the second layer may include a semiconductor, a metal, and/or a transparent conducting material. The first layer may be a semiconductor substrate and the second layer may be a silicon substrate, in which case a surface of the silicon substrate in contact with the third layer may be textured.

The device may also include a top photovoltaic cell and a bottom photovoltaic cell. The first layer may be arranged between the top photovoltaic cell and the third layer, and the second layer may be arranged between the bottom photovoltaic cell and the third layer. A transmittance of the third layer may be at least 80% between a first band gap of the top photovoltaic cell and a second band gap of the bottom photovoltaic cell.

The first layer may be a silicon photovoltaic cell, and the second layer may be a backsheet including a first area of patterned conductors. The photovoltaic cell may include an interdigitated back contact layer that contacts the third layer. The backsheet may also include a second area that is transparent to solar radiation. A surface of the photovoltaic cell in contact with the third layer may be textured.

Other objects, advantages, and novel features of the present invention will become apparent from the following detailed description of the invention when considered in conjunction with the accompanying drawings.

### BRIEF DESCRIPTION OF THE DRAWINGS

FIG. 1 shows a TCA material arranged between a first layer and a second layer;

FIGS. 2(a) and 2(b) show two examples in which the conductive elements are silver-coated plastic microspheres;

FIG. 3 shows a configuration used to measure the series resistance of a TCA material;

FIG. 4 shows a graph of the series resistance as a function of the percent coverage for silver-coated microspheres dispersed in ethylene-vinyl acetate (EVA);

FIGS. 5(a) and 5(b) show configurations for modeling the series resistance of a TCA material;

FIG. 6 shows the transmission as a function of wavelength for glass slides coated with a TCA material having various percentages of silver-coated microspheres dispersed in EVA;

FIG. 7 shows a simplified example of a mechanically stacked tandem cell in which the top cell and the bottom cell are bonded together by a TCA material;

FIG. 8 shows a more detailed example of a mechanically stacked tandem cell;

FIG. 9 shows an example in which a TCA material is used as a rear contact layer for a silicon solar cell; and

FIG. 10 shows an example in which metallic microparticles with dendrites are embedded in a transparent polymer between two layers.

### DETAILED DESCRIPTION

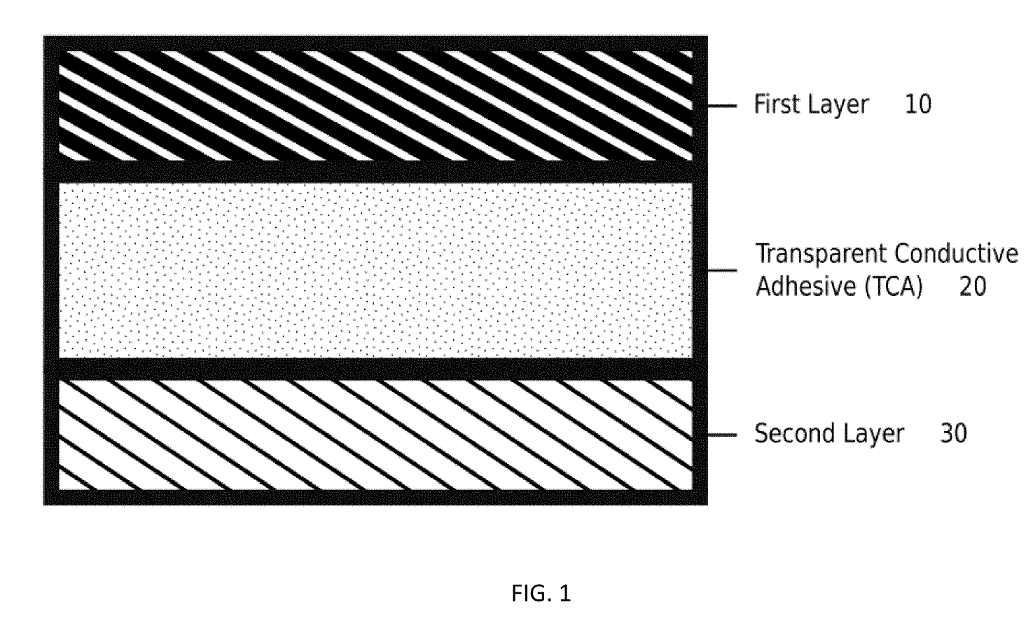

Exemplary embodiments of the invention provide TCA materials with a high optical transparency, such as greater than 80% or 90% transmission over a suitable wavelength range, a low electrical resistance along an out-of-plane (vertical) direction, such as less than 1 Ohm-cm², and adhesive strength to prevent delamination. The TCA material may be a composite material, and may be applied to a variety of surfaces, including textured surfaces, to provide electrical contact between layers. For example, as shown in FIG. 1, the TCA material 20 may be arranged between a first layer 10 and a second layer 30 to provide electrical conductivity between the first layer 10 and the second layer 30.

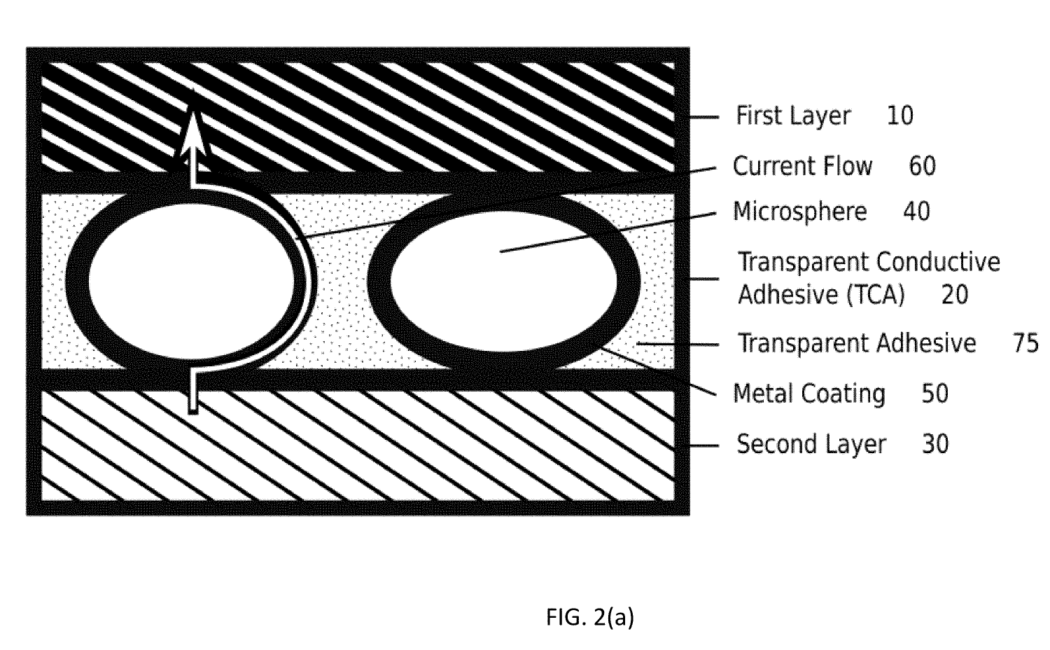

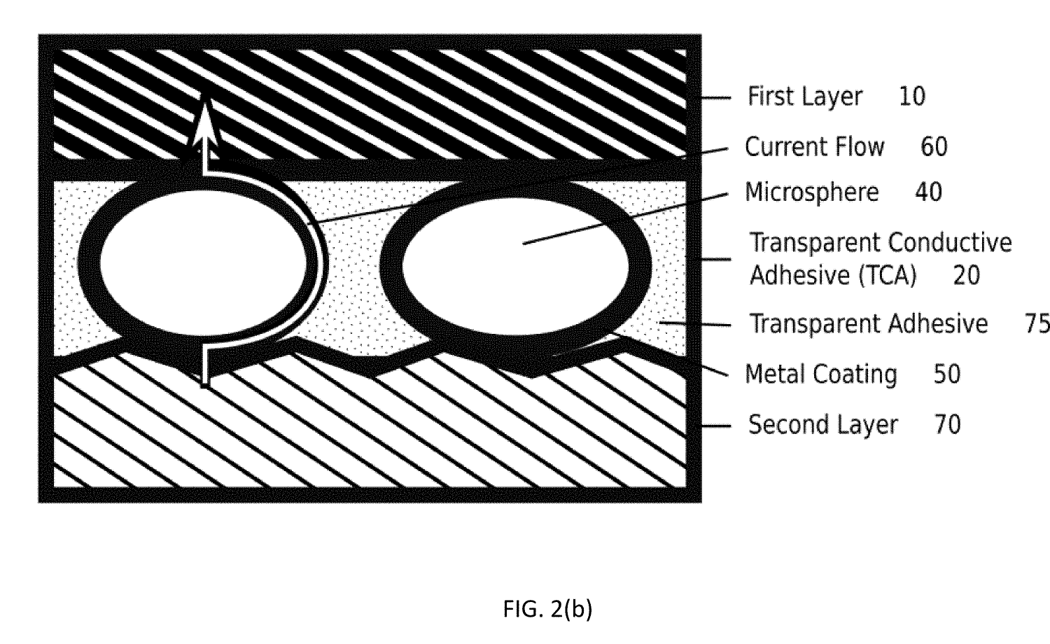

As shown in FIGS. 2(a) and 2(b), the TCA material 20 may include conductive elements, such as microspheres 40, that are dispersed within a transparent adhesive 75 to form a composite material. The transparent adhesive 75 may be any suitable material with sufficient transmittance, such as polysiloxanes, transparent thermoplastics, or transparent copolymers. A few non-limiting examples include poly(methyl methacrylate) (PMMA), polydimethylsiloxane (PDMS), ethylene-vinyl acetate (EVA), cyanoacrylate, polyvinyl butyral (PVB), polyvinyl acetate (PVA), poly(3,4-ethylenedioxythiophene) polystyrene sulfonate (PEDOT:PSS) with d-sorbital, silicone 615a, clear casting epoxy, and loctite eccobond 931-1. The transparent adhesive 75 may be selected to have a transmittance above a threshold over a wavelength region. For example, if the TCA material 20 is used to join the cells of a tandem solar cell, the threshold may be 80% and the wavelength region may be 650-1130 nm. As discussed in further detail below, the wavelength region may be defined by the corresponding band gaps of the solar cells, such as 1.0-1.9 eV. As one example, the transparent adhesive 75 may use EVA pellets dissolved in toluene. Alternatively, other solvents may be used, and adhesive promoters or cross-linkers may be added. For example, additives may be used to increase the adhesive properties, chemical resistance, etc. of the transparent adhesive 75. Further, primers such as Dow Corning 1200 may be applied to one or more of the surfaces that contact the transparent adhesive 75.

The conductive elements may be made of any suitable conductive material. For example, the conductive elements may be plastic spheres that are coated with a metal, with solder, or with a transparent conducting material such as a TCO. The plastic spheres may be made of any suitable material, such as PMMA. Alternatively, the conductive elements may be metal spheres that are attached to metal dendrites that connect the metal spheres to the first layer and/or the second layer. As discussed in further detail below, various other metal structures may also be used as the conductive elements, such as tetrapods and coil structures.

FIGS. 2(a) and 2(b) show two examples in which the conductive elements are silver-coated plastic microspheres 40. As shown in FIG. 2(a), the microspheres 40 may form a monolayer between a flat first layer 10 and a flat second layer 30. For example, the first layer 10 and the second layer 30 may be glass substrates, metal substrates, or semiconductor substrates. The first layer 10 and the second layer 30 may include a transparent conducting material such as a TCO. The first layer 10 and the second layer 30 may be rigid or flexible substrates. There may be a current flow 60 through the metal coating 50, while the dilute nature of the microspheres 40 (˜1-10 wt %) ensures optical transparency and maintenance of the adhesive properties of the matrix. Alternatively, as shown in FIG. 2(b), the microspheres 40 may be used to provide electrical contact between a flat first layer 10 and a textured second layer 70. One or both of the layers may be textured. For example, the first layer 10 may be a glass substrate, and the second layer 70 may be a silicon substrate. In these embodiments, the microspheres 40 may deform when compressed and/or heated to provide additional points of contact between the first layer 10 and the second layer 70.

The microspheres 40 may have any suitable diameter. For example, silver-coated PMMA microspheres 40 with diameters between 5 μm and 135 μm may be selected for their ability to deform in order to bridge uneven, textured surfaces. This provides flexibility in substrates and additional contact points for the smaller diameter microspheres 40, as shown in FIG. 2(b). PMMA microspheres 40 with diameters between 45 μm and 53 μm are particularly suited for bridging the gaps between two independently grown solar cells and allow for increased contact area for individual microspheres 40 when deformed. More generally, the diameter of the microspheres 40 may be between 200 nm and 1000 μm, depending on the application. Individual microspheres 40 within the TCA material 20 may have the same diameter or different diameters.

Advantageously, the TCA material 20 is configured to provide out-of-plane electrical conductivity between the first layer 10 and the second layer 20. Theoretical calculations show that if the contact resistance is neglected, the TCA material 20 is capable of a series resistance of 8·10⁻⁷ Ω-cm² for 10% area coverage (10⁵ particles/cm²). Table I shows the series resistance and transmittance values measured for TCA materials 20 with silver-coated microspheres 40 dispersed within various transparent adhesives.

TABLE I

| Adhesive | Conductive | % | Series | % T. |
|---|---|---|---|---|
| Material | Filler | Coverage | Resistance | (1-1.9 eV) |
| (EVA)- Ethylene | Silver-Coated | 0.8% | 0.10 Ω-cm² | 90% |
| vinyl acetate | PMMA | | | |
| (PMMA)- | Microspheres | 19% | 0.46 Ω-cm² | 75% |
| Poly(methyl | (30-45 μm | | | |
| methacrylate) | OD) | | | |
| Cyanoacrylate | | 3% | 0.99 Ω-cm² | 87% |
| (PVA)- Polyvinyl | | 4% | 1.5 Ω-cm² | 88% |
| acetate | | | | |
| (PVB)- Polyvinyl | | 2% | 6.78 Ω-cm² | 89% |
| butyral | | | | |

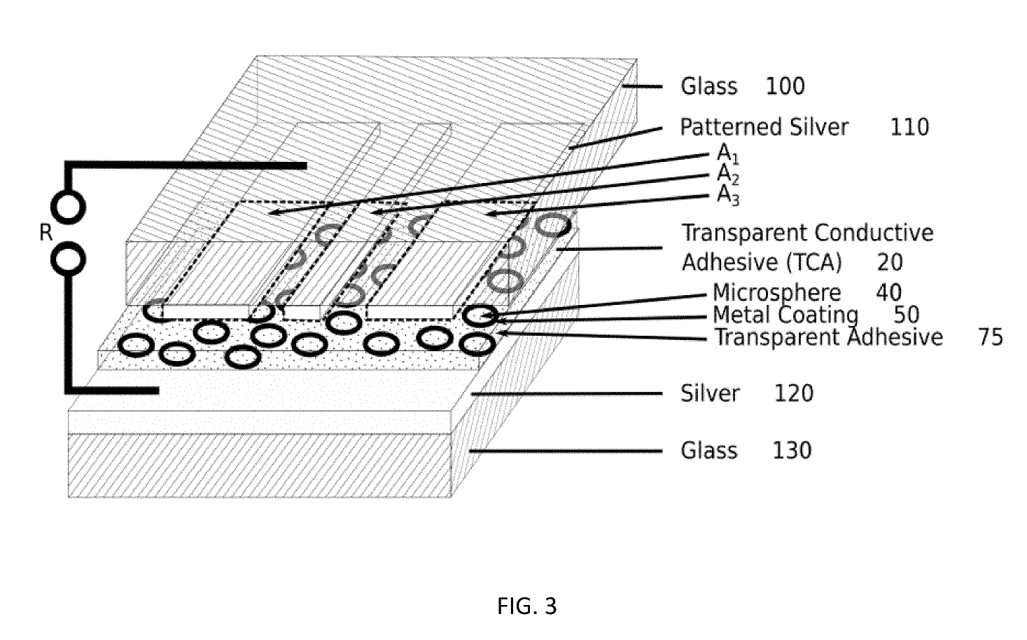

In one example, a composition of EVA pellets dissolved in toluene in a 1:5 ratio was used as the transparent adhesive. In this example, solutions were mixed with varying levels of silver-coated microsphere concentrations using a stir rod. Each solution was characterized by percent coverage using image processing of a glass/glass sample to count the number of particles within a given area. Samples were made in three configurations: (1) glass/TCA/glass, (2) silver-coated glass/TCA/patterned silver-coated glass, and (3) silver-coated textured silicon/TCA/patterned silver-coated glass. FIG. 3 shows an example of configuration (2). As shown in FIG. 3, the TCA material 20 is arranged between glass 100 that is coated with patterned silver 110, and glass 130 that is coated with silver 120. The patterned silver 110 includes a first area A₁, a second area A₂, and a third area A₃. The layers may have any suitable thicknesses. In the example shown in FIG. 3, the thickness of the glass 100 is 1 mm, the thickness of the patterned silver 110 is 150 nm, the thickness of the TCA material 20 is 0.04 mm, the thickness of the silver 120 is 150 nm, and the thickness of the glass 130 is 1 mm.

Using Equation (1) below, the series resistance SR was calculated using the current supplied I, voltage measured V, and first area A₁ shown in FIG. 3. Variation to the area using multiple samples allowed for statistical analysis of the measurements.

$$SR = \frac{V}{I} ( {A}_{1} ) = R ( {A}_{1} ) \qquad Equation ( 1 )$$

Using a hot press in a glove box with temperature control and pressure monitoring, series varying pressure from 0.1 to 10 bar and time from 5 to 60 minutes was performed. The series resistance SR was determined, assuming that a silver contact, which was evaporated onto the glass for testing purposes, has a negligible series resistance. In addition, in-situ measurements were taken during the pressing process.

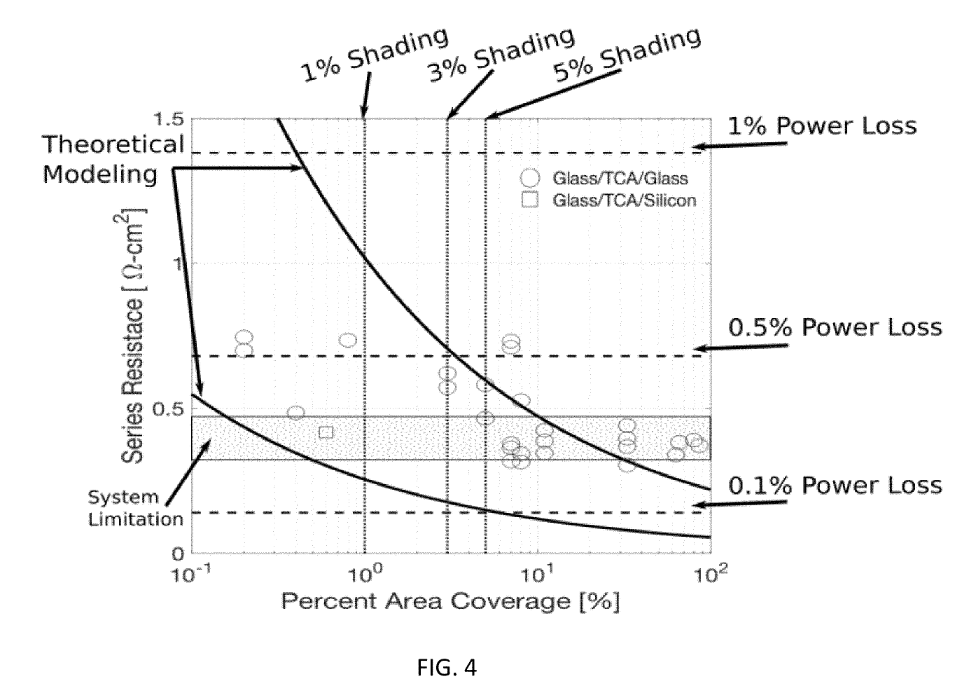

FIG. 4 shows a graph of the series resistance SR as a function of the percent coverage for silver-coated microspheres in EVA. FIG. 4 shows that the series resistance SR decreases as the percent coverage increases, due to additional conductive pathways through the TCA material. The series resistance SR saturates at approximately 0.1 Ω·cm² with approximately 0.8% of silver-coated microspheres in the TCA material. The saturation is caused by a limitation of the measurement equipment, and does not represent a lower limit on the series resistance SR. Instead, as discussed in further detail below, modeling indicates that the series resistance SR should be lower than the saturated value.

For tandem devices, the percent power loss and shading are major factors for evaluating an interlayer. Using a GaInP/Si tandem device with a current-limited top cell (15 mA/cm²), 0.1%, 0.5%, and 1% power loss from the series resistance SR was calculated. For example, FIG. 4 shows that 1% power loss due to resistance in the TCA material corresponds to a series resistance SR of 1.4 Ω-cm², demonstrating that expected power loss from this TCA material is much less than 1%. Furthermore, the shading losses are proportional to the geometric shading; 1%, 3%, and 5% shading are shown in FIG. 4. It can be seen that for the GaInP/Si tandem cell applications, a TCA material with between 0.3% and 1% area coverage will have less than 1% shading loss and less than 0.5% power loss. Within this region, the data point at 0.6% area coverage yields an average series resistance of 0.41 Ω-cm² for a silver patterned glass/TCA/silver-coated as-sawn silicon wafer. This data point demonstrates that the TCA material can be applied to rough Si surfaces without any loss in performance.

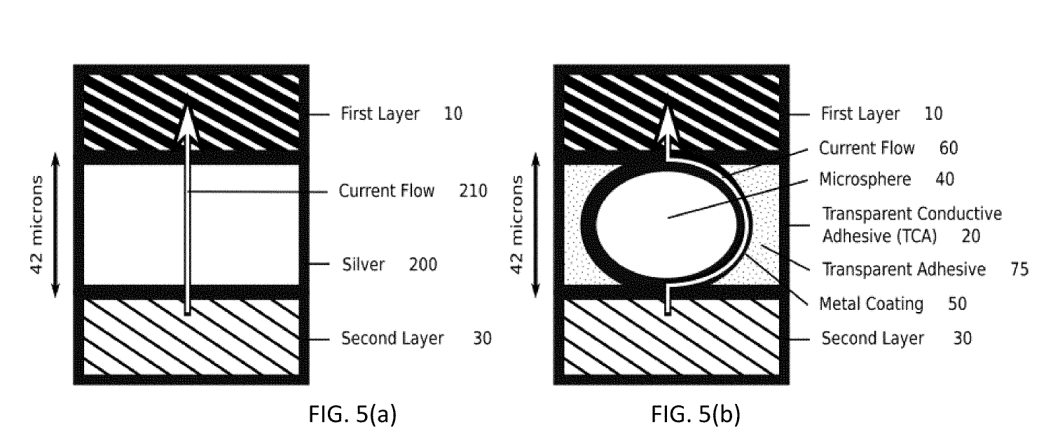

FIGS. 5(a) and 5(b) show configurations for modeling the series resistance SR of the TCA material 20. FIG. 5(a) shows a scenario in which the space between the first layer 10 and the second layer 30 is filled with silver 200, thereby providing a direct connection for current flow 210 from the second layer 30 to the first layer 10. If the distance between the first layer 10 and the second layer 30 is 42 μm, the resistivity of the silver 200 is 6.6·10⁻⁹ Ω-cm². Although the silver 200 used in this scenario is not transparent or adhesive, it indicates the minimum possible series resistance of the TCA material 20. FIG. 5(b) shows a scenario in which a monolayer of silver-coated microspheres 40 is formed between the first layer 10 and the second layer 30. If the distance between the first layer 10 and the second layer 30 is 42 μm, a model shows that the resistivity of the TCA material 20 may be as low as 8·10⁻⁷ Ω·cm² for 10% area coverage, assuming that there is no contact resistance.

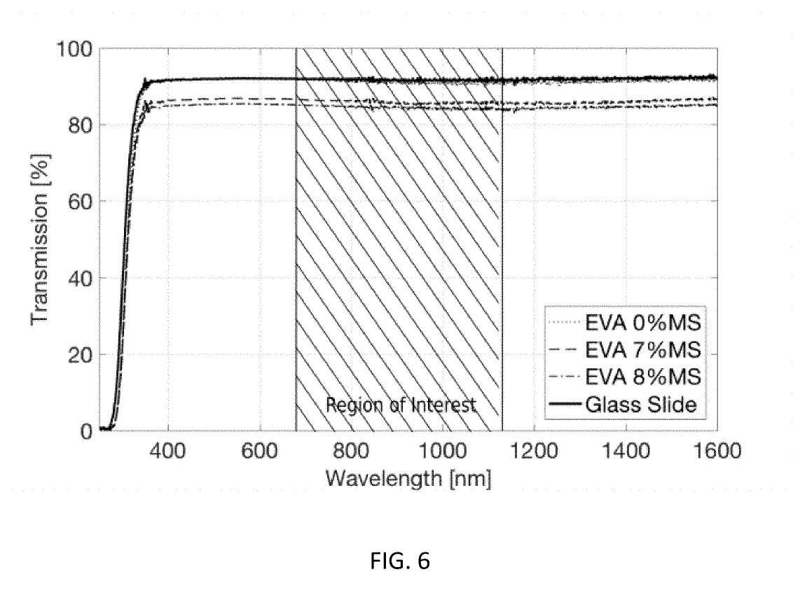

FIG. 6 shows the transmission as a function of wavelength for glass slides coated with a TCA material having EVA as the adhesive material and various percentages of silver-coated microspheres. FIG. 6 shows that the glass slide contributes the majority of optical losses by reflecting 8% of the incident light, roughly 4% from each surface. Table II shows the average transmission in a wavelength range between 680 nm and 1130 nm for these glass slides. As shown in Table II, the EVA has a negligible effect on the transmission, and the transmission decreases as the percentage of silver-coated microspheres increases, due to absorption and reflection from the microspheres. Accordingly, the area coverage of silver-coated microspheres may be adjusted to achieve a desired transmission, based on the application in which the TCA material is being used. To maintain a level of shading from the TCA material that is similar to that of average-sized grid lines (assuming 150 μm wide fingers placed 3 mm apart and having a shading loss of 3%), the area coverage should be below 3%.

TABLE II

| | Average Transmission |
|---|---|
| Percent Coverage | between 680-1130 nm (%) |
| Glass Slide without EVA | 91 |
| EVA without AgMS | 91 |
| 7% AgMS | 86 |
| 11% AgMS | 84 |
| 33% AgMS | 59 |

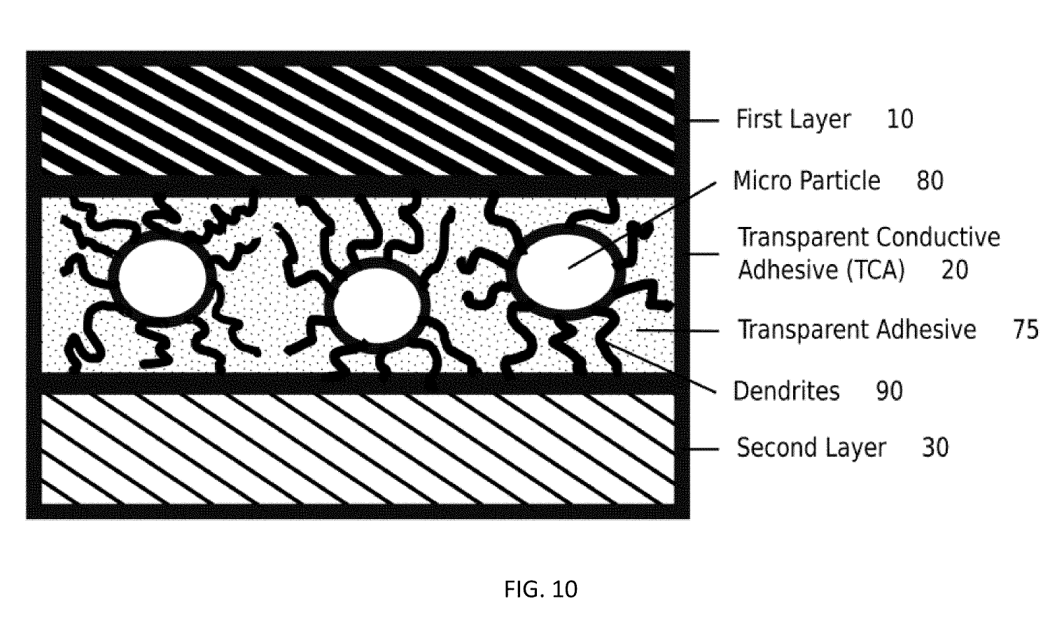

As discussed above, heat treatments may be applied to soften the silver-coated plastic microspheres and ensure optimized contact between the silver and the adjacent surfaces. However, heat treatments may not be necessary, because even at room temperature, the silver-coated plastic microspheres have some compliance, and will compress under pressure. Further, a wide variety of conductive elements could be chosen for different purposes, such as dendritic structures, tetrapods, or coil structures, all of which are deformable under pressure. The deformability allows for better contact between the conductive elements and the adjacent surfaces. Advantageously, these conductive elements may provide primarily or entirely out-of-plane (or vertical) conductivity between the first layer and the second layer. For example, FIG. 10 shows an example in which metallic microparticles 80 with dendrites 90 are embedded in a transparent adhesive 75 between the first layer 10 and the second layer 30.

Further, the TCA material may be tuned to contribute some additional conductivity, if desired. Light scatterers may be added to the TCA material to improve light extraction or reflection. Further, index tunability may be achieved by modifying the transparent adhesive.

The TCA material may be used in a variety of solar cell devices, as well as other applications, such as making contact to either the front or back of a single junction PV device, packaging for other optoelectronic devices such as LEDs, and bonding for other optical devices such as biomedical electrodes and sensors. For example, the TCA material may be used in roll-to-roll processes to laminate substrates together. In addition, the TCA material may serve as a replacement for ITO in organic light-emitting diodes (OLEDs) and flexible electronics, particle polymer blends of carbon nano-tubes, and metal nano-wires.

For example, the TCA material may be used in tandem solar cells using a silicon bottom cell. By combining multiple solar cells with different band gaps, thermalization to the band gap is reduced, thus increasing efficiencies. Wafer bonding is often used to connect multijunction solar cells, but silicon has a textured surface that is incompatible with wafer bonding. Thus, the TCA material serves the same purpose as wafer bonding, but is compatible with a textured surface.

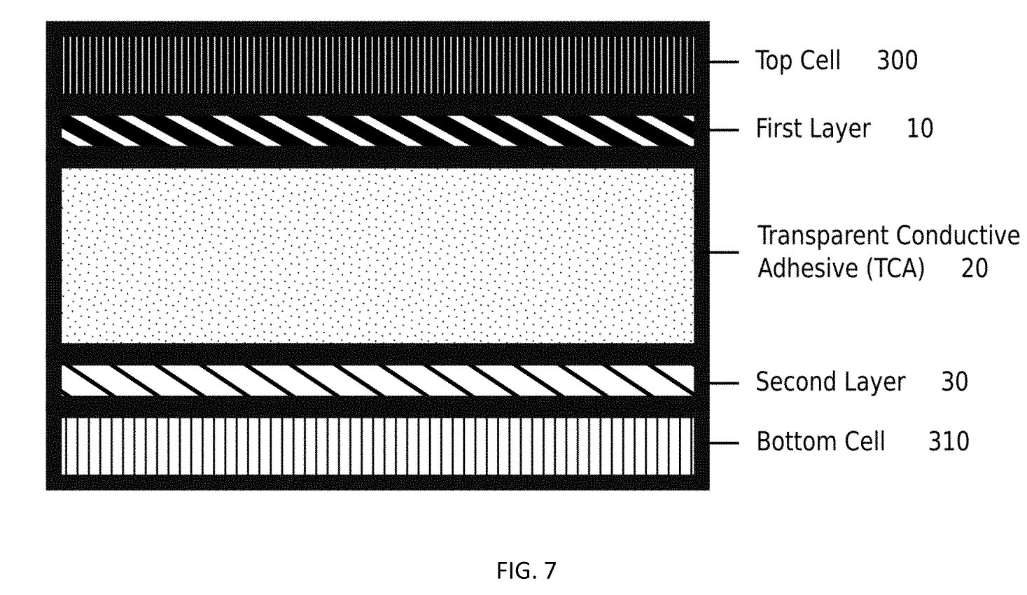

FIG. 7 shows a simplified example of a mechanically stacked tandem cell in which the top cell 300 and the bottom cell 310 are bonded together by a TCA material 20. The TCA material 20 may be deposited on a second layer 30 that is a bottom substrate, and then a first layer 10 that is a top substrate is positioned on top of the TCA material 20. The mechanically stacked tandem cell is then pressed in a hot press for a suitable duration at a suitable temperature and pressure. For example, the pressure should remain below 1 bar, otherwise the microsphere may break and increase the series resistance. The duration may be between 5 and 60 minutes, with a duration of 10 minutes advantageously resulting in a low variability in the measurement of the series resistance.

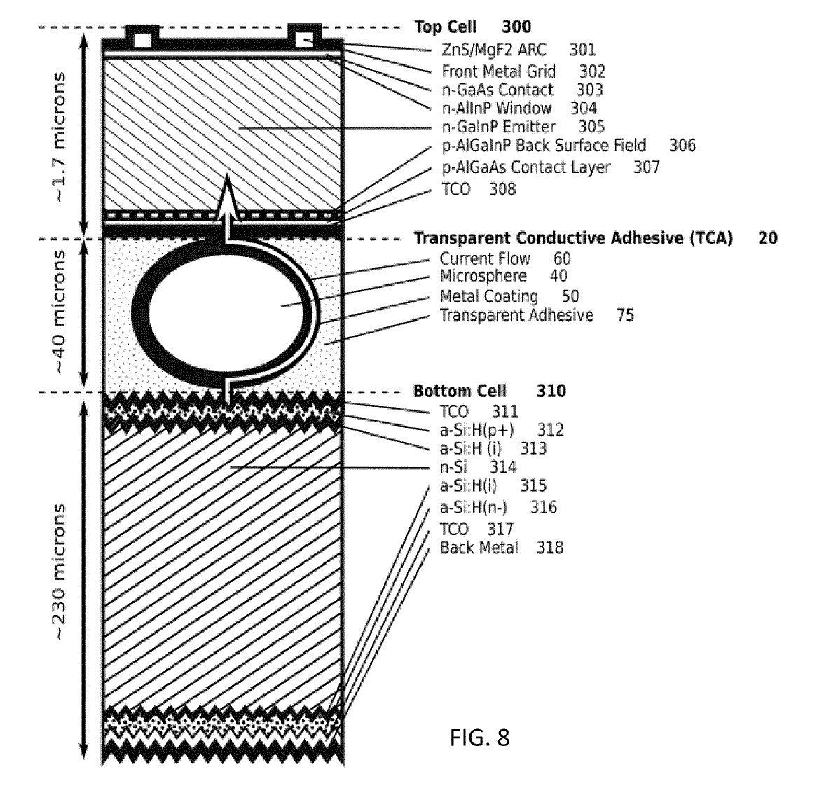

FIG. 8 shows a more detailed example of a mechanically stacked tandem cell. Advantageously, the TCA material 20 provides out-of-plane (vertical) conductivity between the bottom cell 310 and the top cell 300. This is in contrast with related art materials such as silver nanowires, carbon nanotubes, ITO nanoparticles, graphene oxides, and PEDOT:PSS, which have primarily in-plane (lateral) conductivity.

As shown in FIG. 8, the top cell 300 includes a ZnS/MgF₂ anti-reflective coating (ARC) 301, a front metal grid 302, an n-type GaAs contact layer 303, an n-type AlInP window layer 304, an n-type GaInP emitter layer 305, a p-type AlGaInP back surface field layer 306, a p-type AlGaAs contact layer 307, and a TCO layer 308. The top cell 300 may have a thickness of approximately 1.7 μm. The bottom cell 310 includes a TCO layer 311, a p-type amorphous hydrogenated Si layer 312, an intrinsic amorphous hydrogenated Si layer 313, an n-type Si layer 314, an intrinsic amorphous hydrogenated Si layer 315, an n-type amorphous hydrogenated Si layer 316, a TCO layer 317, and a back metal layer 318. The bottom cell 310 may have a thickness of approximately 230 μm. The TCA material 20 may have a thickness of approximately 40 μm.

For tandem solar cell applications, the wavelengths for which the TCA material should be transparent are between the band gaps of the two solar cells (i.e., below the band gap of the top cell and above the band gap of the lower cell). For example, if the bottom cell 310 has a band gap of 1.1 eV and the top cell 300 has a band gap of 1.9 eV, the TCA material 20 should be transparent in a wavelength range from approximately 650 nm to approximately 1130 nm. As discussed above, FIG. 6 shows the transmission data from samples of plain glass, EVA without microspheres, and varied percent coverage of silver-coated microspheres in EVA. These data show that the glass slide dominated transmission losses due to its reflectance. With 92% T through a single glass slide and 91% T for the EVA with 0% microspheres, the transmission is within the margin of error, and no additional losses are seen from the EVA layer. Increasing to 7% microspheres, the transmission is reduced to 86% T, and 8%, 11% and 33% microspheres similarly show reductions to 84% T, 83% T and 59% T, respectively. Remaining in the percent coverage where less than 20% is absorbed and translating this into shading loses on the silicon cell, a minimal loss is expected. For decreasing interfacial reflections and absorption, various coatings may be applied to mitigate these effects.

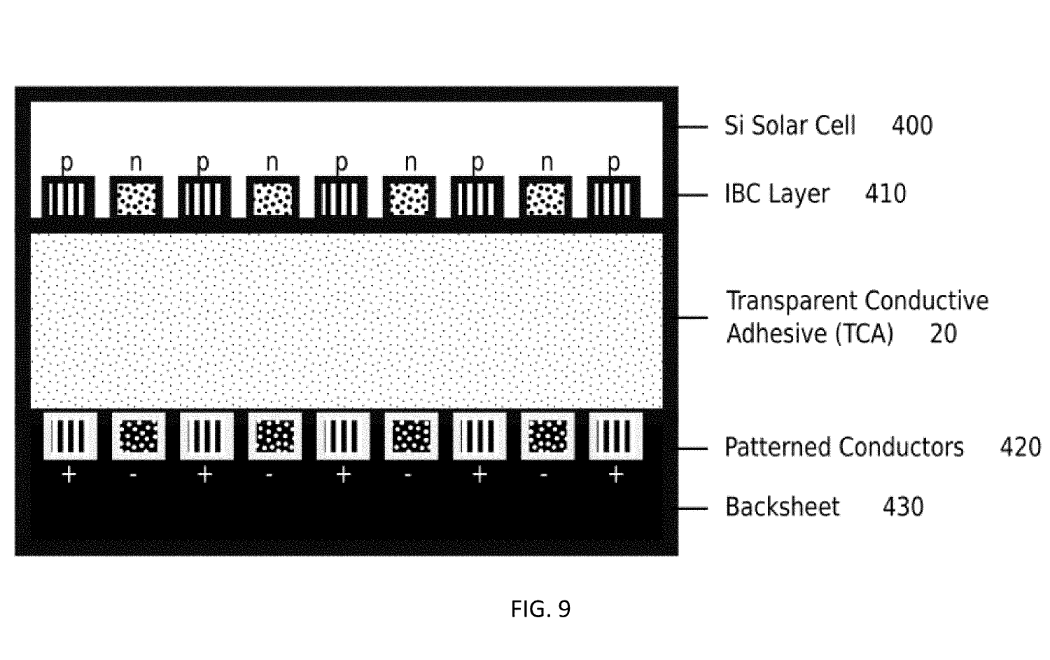

In another example shown in FIG. 9, the TCA material 20 may be used as a rear contact layer for a Si solar cell 400. The TCA material 20 may include metal-coated microparticles dispersed in a first polymer, and may achieve a series resistance of less than 1 Ω·cm² along the out-of-plane (vertical) direction. The first polymer may be a solar encapsulant material such as EVA. The microparticles may be microspheres made of a second polymer, and may have a diameter between 10 μm and 1000 μm. The metal coating on the microparticles may be able to soften, melt, and/or solder when heated and/or pressed. A rear surface of the silicon solar cell 400 that contacts the TCA material 20 may be textured.

The TCA material 20 may have greater than 90% transparency to solar illumination that is transmitted in the first pass through the solar cell 400 and is above the band gap of the solar cell 400. The TCA material 20 may impart an improved rear reflectivity to the solar cell 400. The TCA material 20 may be conductive in the out-of-plane (vertical) direction, but not in the in-plane (lateral) direction. In other words, the TCA material 20 may provide unidirectional conductivity from one planar surface to another planar surface without lateral current spreading. This may be a desirable feature, for example, in interdigitated back contact (IBC) solar cells, because the current would not travel between adjacent p and n regions of the IBC layer.

As shown in FIG. 9, the TCA material 20 may be incorporated into a PV module having a backsheet 430 with a first area of patterned conductors 420. The patterned conductors 420 may be made of any suitable metal, such as Al or Cu. The patterned conductors 420 may form alternating areas of positive and negative metal grids, which may correspond to the p and n regions of an IBC layer 410 on the back side of the Si solar cell 400. A second area of the backsheet 430 excluding the patterned conductors may be transparent to the solar illumination. Heat and/or pressure may be used to form the PV module shown in FIG. 9.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A device comprising:
a first layer;
a second layer; and
a third layer comprising a transparent and conductive adhesive (TCA) material, wherein:
the third layer is arranged between the first layer and the second layer, and is configured to provide electrical conductivity between the first layer and the second layer,
the TCA material comprises conductive elements dispersed within a transparent adhesive, and
the conductive elements are deformable.

2. The device according to claim 1, wherein the conductive elements comprise plastic spheres that are coated with metal.

3. The device according to claim 2, wherein the plastic spheres comprise poly(methyl methacrylate) (PMMA).

4. The device according to claim 1, wherein an area percent coverage of the conductive elements within the transparent adhesive is below 22.

5. The device according to claim 1, wherein a diameter of each of the conductive elements within the transparent adhesive is between 200 nm and 1000 μm.

6. The device according to claim 5, wherein the diameter is between 45 μm and 53 μm.

7. The device according to claim 1, wherein the conductive elements comprise metal spheres with dendrites that connect the metal spheres to the first layer or the second layer.

8. The device according to claim 1, wherein the transparent adhesive comprises ethylene-vinyl acetate (EVA).

9. The device according to claim 1, wherein a series resistance of the third layer along a direction perpendicular to a plane of the third layer is less than 1 Ω·cm².

10. The device according to claim 9, wherein the third layer is configured to provide no electrical conductivity along a direction parallel to the plane of the third layer.

11. The device according to claim 1, wherein at least one of the first layer or the second layer comprises a semiconductor.

12. The device according to claim 1, wherein at least one of the first layer or the second layer comprises a metal.

13. The device according to claim 1, wherein at least one of the first layer or the second layer comprises a transparent conducting material.

14. The device according to claim 1, wherein the first layer is a semiconductor substrate and the second layer is a silicon substrate, and a surface of the silicon substrate in contact with the third layer is textured.

15. The device according to claim 1, further comprising:
a top photovoltaic cell; and
a bottom photovoltaic cell, wherein:
the first layer is arranged between the top photovoltaic cell and the third layer, and
the second layer is arranged between the bottom photovoltaic cell and the third layer.

16. The device according to claim 15, wherein a transmittance of the third layer is at least 80% between a first band gap of the top photovoltaic cell and a second band gap of the bottom photovoltaic cell.

17. The device according to claim 1, wherein:
the first layer is a photovoltaic cell, and
the second layer is a backsheet comprising a first area of patterned conductors.

18. The device according to claim 17, wherein the photovoltaic cell comprises an interdigitated back contact layer that contacts the third layer.

19. The device according to claim 17, wherein the backsheet further comprises a second area that is transparent to solar radiation.

20. The device according to claim 17, wherein a surface of the photovoltaic cell in contact with the third layer is textured.
